(19) United States
(12) Patent Application Publication
(10) Pub. No.: US 2005/0057900 A1
(43) Pub. Date: Mar. 17, 2005

(54) Heat dissipating circulatory system with sputtering assembly

(75) Inventors: Ga-Lane Chen, Fremont, CA (US); Charles Leu, Fremont, CA (US)

Correspondence Address: MORRIS MANNING & MARTIN LLP, 1600 ATLANTA FINANCIAL CENTER, 3343 PEACHTREE ROAD, NE, ATLANTA, GA, 30326-1044, US

(73) Assignee: HON HAI Precision Industry Co., LTD., Tu-Cheng City (TW)

(21) Appl. No.: 10/975,771

(22) Filed: Oct. 28, 2004

(30) Foreign Application Priority Data
May 12, 2003 (TW) 92221442

(51) Int. Cl. H05K 5/00; H05K 7/20

(52) U.S. Cl. 361/698

(57) ABSTRACT

A heat dissipating circulatory system (8) includes a pool (7) for receiving an operating fluid, a pump (3), a heat spreader (2) and a condenser (4). A first pipe (51) interconnects an output end (42) of the condenser and an input end (71) of the pool. A second pipe (52) interconnects an output end (72) of the pool and an input end (31) of the pump. A third pipe (53) interconnects an output end (32) of the pump and an input end (21) of the heat spreader. A fourth pipe (54) interconnects an output end (22) of the heat spreader and an input end (41) of the condenser. The heat spreader includes a fin (13) and a liquid sputtering assembly (1). The liquid sputtering assembly includes a plurality of nozzles (11) and drivers (12). The operating fluid is directly sputtered onto the fin, thereby providing direct heat exchange.

### BACKGROUND OF THE INVENTION

1. Field of the Invention

The invention relates generally to heat dissipating circulatory systems for dissipating heat from heat-generating apparatus or components, and more particularly to a heat dissipating circulatory system with a sputtering assembly and using a liquid operating fluid.

2. Description of the Prior Art

The operating speed of electronic apparatus such computers, printers and copiers is becoming progressively higher, and is due in large part to the increase in electronic transmissions speeds of components of these apparatus. Correspondingly, the heat dissipation requirements of these components are increasing too. In many contemporary applications, a fan is fixed on or near such electronic components to dissipate heat. The fan dissipates heat by utilizing air as the operating medium. Generally, however, the heat dissipating efficiency of the fan is relatively poor. Heat produced in the electronic components cannot be dissipated timely and efficiently. Furthermore, the fan is prone to produce noise during operation.

Various devices have been developed in order to dissipate the heat timely and efficiently, and to avoid noise. For example, China Pat. No. 99210734.2 discloses a heat dissipating device using a liquid operating fluid. The heat dissipating device is adapted to be used for a computer, and comprises a cooling pipe, a pump, at least a fin, and at least a heat dissipating portion. The cooling pipe receives the liquid operating fluid therein, and the pump is fixed in a suitable position along the cooling pipe. The fin is fixed to a heat-generating chip in the computer, and comprises a first pipe connected with the cooling pipe. The heat dissipating portion is fixed to an outer surface of the computer, and comprises a second pipe connected with the cooling pipe. The liquid operating fluid circulates in a same direction through the heat dissipating device, and the heat produced by the chip is dissipated to the external environment. A heat dissipating efficiency of the heat dissipating device is relatively high, and no appreciable noise is generated.

In the above-mentioned heat dissipating device, the operating fluid is driven by the pump to flow into the first pipe of the fin, and absorbs the heat produced by the chip from the fin via the first pipe. Then the operating fluid is driven by the pump to flow into the second pipe of the heat dissipating portion, and dissipates the heat to the external environment via the heat dissipating portion. Because the heat exchange between the operating fluid and the fin must be via the first pipe of the fin, the heat dissipating device does not provide direct heat exchange. This effectively reduces the efficiency of the heat dissipating device.

A new heat dissipating circulatory system which overcomes the above-mentioned problems is desired.

### BRIEF SUMMARY OF THE INVENTION

Accordingly, an object of the present invention is to provide a heat dissipating circulatory system which can achieve timely and efficient heat exchange.

To fulfill the above-mentioned object, the present invention provides a heat dissipating circulatory system comprising a pool for receiving an operating fluid, a pump, a heat spreader and a condenser. A first pipe interconnects an output end of the condenser and an input end of the pool. A second pipe interconnects an output end of the pool and an input end of the pump. A third pipe interconnects an output end of the pump and an input end of the heat spreader. A fourth pipe interconnects an output end of the heat spreader and an input end of the condenser. The heat spreader comprises a fin and a liquid sputtering assembly. The liquid sputtering assembly comprises a plurality of liquid sputtering elements, and each liquid sputtering element comprises a nozzle and a driver.

The operating fluid is directly sputtered onto the fin via the nozzles. Thus, direct heat exchange occurs between the operating fluid and the fin, unlike in conventional heat dissipating devices. This ensures that the heat exchange between the operating fluid and the fins is timely and efficient, and improves a heat dissipating efficiency of the heat dissipating circulatory system.

Other objects, advantages and novel features of the invention will become more apparent from the following detailed description when taken in conjunction with the accompanying drawings, in which:

### BRIEF DESCRIPTION OF THE DRAWINGS

FIG. 1 is a block diagram of a heat dissipating circulatory system of the present invention;

FIG. 2 is a schematic, side elevation of a heat spreader of the heat dissipating circulatory system of FIG. 1; and

FIG. 3 is an enlarged, schematic end elevation of a liquid sputtering assembly of the heat spreader of FIG. 2.

### DESCRIPTION OF THE PREFERRED EMBODIMENT

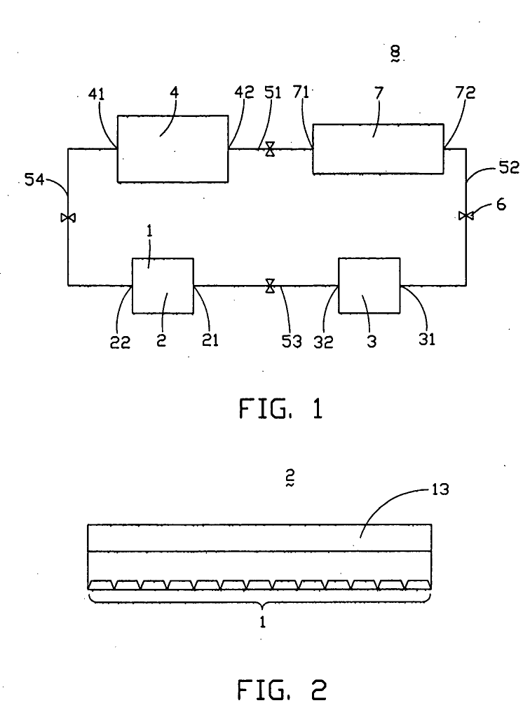

Referring to FIG. 1, a heat dissipating circulatory system 8 of the present invention comprises a pool 7 as a reservoir for receiving an operating fluid (not shown), a pump 3 as a circulating driver, a heat spreader 2, and a condenser 4. A first pipe 51 interconnects an output end 42 of the condenser 4 and an input end 71 of the pool 7. A second pipe 52 interconnects an output end 72 of the pool 7 and an input end 31 of the pump 3. A third pipe 53 interconnects an output end 32 of the pump 3 and an input end 21 of the heat spreader 2. A fourth pipe 54 interconnects an output end 22 of the heat spreader 2 and an input end 41 of the condenser 4.

The pump 3 is used to drive the operating fluid to flow in a same direction through the heat dissipating circulatory system 8. In the preferred embodiment, the pump 3 is a micro pump.

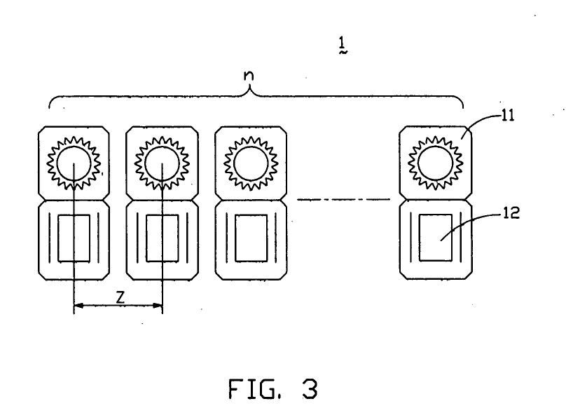

Referring to FIGS. 2 and 3, the heat spreader 2 comprises a fin 13 and a corresponding liquid sputtering assembly 1. The fin 13 is flat and made of aluminum or copper. The fin 13 is located at a heat source (not shown), and absorbs heat produced by the heat source. The liquid sputtering assembly 1 comprises a plurality of (“n”) liquid sputtering elements (not labeled), and each liquid sputtering element comprises a nozzle 11 and a driver 12. A pitch Z between each two adjacent liquid sputtering elements is in the range from 5 micrometers to 50 micrometers.

A plurality of check valves 6 are fixed to the first, second, third and fourth pipes 51, 52, 53, 54 respectively. The check valves 6 are used to control a speed and direction of flow of the operating fluid.

In the preferred embodiment, the operating fluid comprises pure water and a plurality of nanometer-scale particles suspended in the pure water. The nanometer-scale particles are nanometer-scale copper particles, carbon nanotubes or carbon nanocapsules. Because the nanometer-scale particles are extremely small and have high thermal conductivity, this ensures that the operating fluid has high thermal conductivity. In alternative embodiments, the pure water can be replaced by heptane.

An operating process of the heat dissipating circulatory system 8 is as follows. Firstly, the pump 3 draws operating fluid out of the pool 7 via the second pipe 52. The operating fluid flows into the heat spreader 2 via the third pipe 53. There, the operating fluid is driven by the drivers 12 of the liquid sputtering assembly 1 to directly sputter onto the fin 13 via the nozzles 11 of the liquid sputtering assembly 1. At the same time, direct heat exchange occurs between the fin 13 and the operating fluid. The heat absorbed by the fin 13 is transmitted to the operating fluid, and the temperature of the liquid operating fluid rises. Then, the heated operating fluid is driven by a pump (not shown) connected with the liquid sputtering assembly 1 to flow into the condenser 4 via the fourth pipe 54. The condenser 4 cools the operating fluid, the heat absorbed in the operating fluid is transmitted to the external environment, and the temperature of the operating fluid falls. Finally, the cooled operating fluid flows into the pool 7 via the first pipe 5l. The heat dissipating circulatory system 8 thus continues this circulatory process of transmitting heat.

Compared with a conventional heat dissipating device, the heat dissipating circulatory system 8 of the present invention has the following advantages. The operating fluid is directly sputtered onto the fin 13 via the nozzles 11. Thus, direct heat exchange occurs between the operating fluid and the fin 13. This ensures that the heat exchange between the operating fluid and the fins 13 is timely and efficient, and improves a heat dissipating efficiency of the heat dissipating circulatory system 8.

It is to be understood that the above-described embodiment is intended to illustrate rather than limit the invention. Variations may be made to the embodiment without departing from the spirit of the invention. Accordingly, it is appropriate that the appended claims be construed broadly and in a manner consistent with the scope of the invention.

1. A circulatory system for dissipating heat, the circulatory system comprising: a condenser;
a pool for receiving an operating fluid and with an input end thereof interconnected with an output end of the condenser by a first pipe;
a pump with an input end thereof interconnected with an output end of the pool by a second pipe;
a heat spreader with an input end thereof interconnected with an output end of the pump by a third pipe, and with an output end thereof interconnected with an input end of the condenser by a fourth pipe;
wherein the heat spreader comprises a fin and a liquid sputtering assembly, the liquid sputtering assembly comprises a plurality of liquid sputtering elements, and each liquid sputtering element comprises a nozzle and a driver.

2 The circulatory system as claimed in claim 1, wherein a plurality of check valves are fixed to the first, second, third and fourth pipes respectively.

3. The circulatory system as claimed in claim 1, wherein the operating fluid is water or heptane.

4. The circulatory system as claimed in claim 3, wherein a plurality of nanometer-scale particles are suspended in the operating fluid.

5. The circulatory system as claimed in claim 4, wherein the nanometer-scale particles are nanometer-scale copper particles, carbon nanotubes and/or carbon nanocapsules.

6. The circulatory system as claimed in claim 1, wherein a pitch between each two adjacent liquid sputtering elements is in the range from 5 micrometers to 50 micrometers.

7. The circulatory system as claimed in claim 1, wherein the fin is flat and made of aluminum or copper.

8. The circulatory system as claimed in claim 1, wherein the pump is a micro pump.

9. A heat dissipating system comprising:
a fluid reservoir for receiving an operating fluid;
a fluid driver for driving said operating fluid out of said fluid reservoir; and
a heat spreader for receiving said operating fluid from said fluid reservoir and further forcedly sputtering said operating fluid out of said heat spreader for heat dissipating before said operating fluid returns to said fluid reservoir.

10. The heat dissipating system as claimed in claim 9, wherein said heat spreader has a nuzzle for sputtering.

11. The heat dissipating system as claimed in claim 10, wherein said heat spreader further comprises a driver to supply sputtering power for said nuzzle.

12. The heat dissipating system as claimed in claim 10, wherein said heat spreader further comprises a fin disposed before said nuzzle for heat-interchanging with said sputtered operating fluid.

13. The heat dissipating system as claimed in claim 9, wherein said operating fluid comprises a plurality of nanometer-scale particles suspended therein.

14. A method for heat dissipating comprising the steps of:
reserving an operating fluid;
driving said reserved operating fluid for circulating; and
sputtering said operating fluid during said fluid circulating.

15. The method as claimed in claim 14, wherein a row of nozzles is used for sputtering in said sputtering step.

16. The method as claimed in claim 14, wherein said operating fluid has a plurality of nanometer-scale particles suspended therein.
